(19) United States
(12) Patent Application Publication
(10) Pub. No.: US 2002/0086506 A1
(43) Pub. Date: Jul. 4, 2002

(54) Method of fabricating an integrated circuit processed on both sides

(76) Inventors: Wolfgang Angermann, Seeshaupt (DE); Michael Pfeiffer, Munchen (DE)

Correspondence Address: LERNER AND GREENBERG, P.A., POST OFFICE BOX 2480, HOLLYWOOD, FL, 33022-2480, US

(21) Appl. No.: 10/008,785

(22) Filed: Nov. 13, 2001

(30) Foreign Application Priority Data
Nov. 10, 2000 (DE) 100 55 848.8

(51) Int. Cl. H01L 21/20

(52) U.S. Cl. 438/584

(57) ABSTRACT

A silicon wafer with a thickness of the order of magnitude of 0.8 mm is firstly processed at least partially on a first side. The unthinned silicon wafer is subsequently provided, on the second side, with a second circuit structure and a metallization structure arranged above the latter. The electrical insulation of the two circuit structures is effected solely by the intermediate undoped silicon material of the wafer. The two metallization structures are connected to an external contact-making structure.

### BACKGROUND OF THE INVENTION

Field of the Invention

The invention lies in the field of integrated technology processing and relates, more specifically, to a method of producing an integrated circuit that is processed on both sides.

A method of that type is disclosed for example in German published patent application DE 198 53 703 A1 (see also PCT publication WO 00/31796).

Integrated semiconductor chips have hitherto been manufactured exclusively from wafers processed on one side. The structures thereby fabricated on the front side of the wafers have been produced using the method steps known from customary semiconductor technology, such as diffusion, coating, etching, and the like. The rear side of the wafer has, accordingly, not been patterned but rather has served essentially only as a bearing surface of the wafer in the various processing stations. Three-dimensional structures have hitherto been realized only in the limited sense that one or more wiring planes—but no circuit structures—have been produced on the rear side of the wafer and connected via plated-through holes to the metallization structure on the patterned front side of the wafer. Structures have also been disclosed wherein two individual wafers patterned on one side are subsequently joined together to form a construction provided with circuit structures on both sides.

The method disclosed very recently in the above-mentioned German disclosure DE 198 53 703 A1, is essentially based on an electrically insulating oxide layer buried in the substrate, so that it is possible to apply a circuit structure on both sides of the oxide layer. In the simplest case, firstly a wafer, which is processed above the implanted oxide layer and is provided with plated-through holes is fabricated, which wafer is subsequently reverse-bonded onto a handling wafer, thinned on the rear side and then provided with circuit and metallization structures on the rear side. In order that the handling wafer (wafers) used in this case is (are) applied to the wafer, which is then to be processed further on the opposite side, by means of an adhesive bond, the construction proposed also contains planarization planes.

### SUMMARY OF THE INVENTION

It is accordingly an object of the invention to provide a method of producing an integrated circuit structure, which overcomes the above-mentioned disadvantages of the heretofore-known devices and methods of this general type and which, for better utilization of the wafer surface, provides both the front side and the rear side of the wafer with circuit structures and further structures. It is the main object to create vertically integrated circuits which can be fabricated in a manner that, overall, is not very complicated.

With the foregoing and other objects in view there is provided, in accordance with the invention, a method of fabricating an integrated circuit, which comprises:

providing a silicon wafer having a first side, a second side, and a thickness of the order of magnitude of 0.8 mm;

forming a first circuit structure on the first side and a metallization structure on the first circuit structure;

forming a second circuit structure on the second side of the unthinned silicon wafer and a metallization structure on the second circuit structure, whereby the first and second circuit structures are electrically insulated from one another solely by an undoped silicon material of the silicon wafer disposed therebetween; and

producing contact-making structures for connecting the metallization structures on the first and second circuit structures.

The first and second circuit structures are each formed with individual circuits defined within chip outlines, and the contact-making structures are formed for the metallization structure of each individual circuit chip. The wafer is subsequently diced (e.g., sawed) into individual chips.

In other words, the method comprises the following:

a silicon wafer having a thickness of the order of magnitude of 0.8 mm is provided, on a first side, with a first circuit structure and a metallization structure arranged above the latter;

the unthinned silicon wafer is provided, on the second side, with a second circuit structure and a metallization structure arranged above the latter, the electrical insulation of the two circuit structures being effected solely by the intervening undoped silicon material of the wafer;

and a contact-making structure for connecting the two metallization structures of each individual circuit (chip) is produced.

The invention is firstly based on the insight that there are no fundamental physical reasons, for example with regard to the crystal orientation, standing in the way of processing a silicon wafer on both sides. What is crucial, furthermore, is the fact that the customary implantations (basic doping) and diffusions take place only as far as a material depth of about 50 μm. The initial thickness of a silicon wafer is currently about 0.8 mm and is reduced by grinding to about 0.2 mm before insertion into a housing. Even with this small wafer thickness, although there would still be an electrically sufficient insulation zone made of undoped silicon material between the circuit structures arranged on both sides of the wafer, very considerable flexure of the wafer would already be produced given a wafer thickness of only 0.2 mm. Such flexure is undesirable according to the invention, since it would make the handling of the wafer much too difficult.

According to the invention, twice the chip area is made available without requiring an additional insulation layer, since the new method is not based on grinding the wafer, after the processing of its front side, from its rear side to such a great extent that the electrical isolation of the two circuit structures is jeopardized. According to the invention, the wafer or the individual chip accordingly retains its initial thickness, in terms of order of magnitude, until it is housed. A particularly advantageous refinement of the method consists in the fact that the silicon wafer processed on both sides is provided with connection pads on both sides, and that the connection pads of both sides are connected via an external contact-making structure, in particular a leadframe, after the silicon wafer has been sawn into individual chips. This leadframe may be arranged approximately in the central plane of the chip, which is held in the leadframe by means of bonding wires. The handling during the successive bonding of the first side of the chip to the top side of the leadframe and then of the second side of the chip to the underside of the leadframe is only slightly more complicated than hitherto.

Although the invention also encompasses the possibility of an internal contact-making structure, for example via the plated-through holes known per se, the latter can only be fabricated in a relatively complicated manner even in connection with the uncovering of the plated-through holes in the course of grinding the wafer. In the case of unthinned wafers with circuit structures present on both sides, with a respectively assigned metallization structure, it would be necessary, however, to implement adequate measures for achieving the high alignment accuracy required.

Other features which are considered as characteristic for the invention are set forth in the appended claims.

Although the invention is illustrated and described herein as embodied in a method for fabricating an integrated circuit processed on both sides, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments.

### DESCRIPTION OF THE PREFERRED EMBODIMENTS

Processing the wafer on both sides in accordance with the invention is advantageously associated with changes in the handling, since the wafer, at the latest as soon as it has been (partially) processed on a first side, can no longer, in contrast to the conventional prior art situation, simply be mounted in a planar manner on this side. In order to avoid damage, and at the same time to be able to utilize the largest possible region of the wafer surface, it is proposed that the silicon wafer be mounted only in the region of its periphery. This can be done for example by means of a ring or multipoint bearing. Wafer transport processes can be carried out, for example, by means of sickle-shaped grippers.

The proposed bearing only in the region of the periphery of the wafer may require, depending in particular on the wafer thickness and the wafer diameter, compensation of the slightly sagging wafer due to the dead weight. The surface of the wafer should be kept absolutely plane in order to prevent imaging faults during exposure in the course of the patterning processes. Monitoring can be effected for example by means of interferometric aids. The compensation of the flexure of the silicon wafer resting on a ring or multipoint bearing could be realized for example by air pressure. According to the invention, a jet of air directed from the bottom vertically upward against the central region of the silicon wafer should suffice as a counterforce for stabilizing the silicon wafer in the horizontal, which would no longer be the case given wafer thicknesses of about 0.2 mm on account of the higher elasticity.

In this connection, a plurality of conversion and alignment steps may be necessary in order to balance the wafer with regard to the process axis, since resist or polishing processes, in particular, can only be effected on one side. On the other hand, according to the invention, it is possible to dispense with the (multiple) reverse-bonding of the wafer onto a handling wafer and an adhesive bond. Dicing, that is the sawing of the wafer into the individual chips, is also readily possible.

It is a further particularly advantageous feature of the method according to the invention that furnace processes, for example CVD layer depositions, can be effected simultaneously on both sides of the wafer. During heat treatment processes, which penetrate through the wafer and anneal process damage as a result of heating, care must be taken to ensure that these take place according to a schedule which is valid for both wafer sides.

In principle, the silicon wafer can accordingly be completed, according to the invention, either, while utilizing the above-mentioned furnace processes on both sides, by means of single-side process steps that are carried out alternately on both sides, or by complete processing firstly of a first side and then of a second side.

Since the wafer is no longer ground down to the small thickness of about 0.2 mm that is customary nowadays, modified housings must be required, also with regard to the external contact-making structure. On the other hand, for a given scope of circuitry, the patterning on both sides results, of course, in a reduced area requirement for the individual chip.

We claim:

1. A method of fabricating an integrated circuit, which comprises:
providing a silicon wafer having a first side, a second side, and a thickness of the order of magnitude of 0.8 mm;
forming a first circuit structure on the first side and a metallization structure on the first circuit structure;
forming a second circuit structure on the second side of the unthinned silicon wafer and a metallization structure on the second circuit structure, whereby the first and second circuit structures are electrically insulated from one another solely by an undoped silicon material of the silicon wafer disposed therebetween; and
producing contact-making structures for connecting the metallization structures on the first and second circuit structures.

2. The method according to claim 1, wherein the first and second circuit structures are each formed with individual circuits, and the producing step comprises forming a contact-making structure for the metallization structure of each individual circuit.

3. The method according to claim 2, which comprises subsequently dicing the wafer into individual chips each having a first circuit, a second circuit, and a contact-making structure.

4. The method according to claim 1, which comprises handling the silicon wafer with holding aids on which the silicon wafer is mounted only at a periphery.

5. The method according to claim 4, which comprises compensating for a flexure of the silicon wafer by a counterforce for stabilizing the wafer surface in the horizontal.

6. The method according to claim 1, which comprises forming connection pads on both sides of the silicon wafer, dicing the wafer into individual chips, and subsequently connecting the connection pads of both sides via an external contact-making structure.

7. The method according to claim 6, which comprises providing a leadframe as the external contact-making structure.
